(19) United States
(12) Patent Application Publication
(10) Pub. No.: US 2009/0107834 A1
(43) Pub. Date: Apr. 30, 2009

(54) CHALCOGENIDE TARGET AND METHOD

(75) Inventors: Mengqi Ye, Milpitas, CA (US); Rong Tao, San Jose, CA (US); Hua Chung, San Jose, CA (US); Goichi Yoshidome, Emeryville, CA (US); William Rhodes, Sunnyvale, CA (US); Peijun Ding, Saratoga, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/927,605

(22) Filed: Oct. 29, 2007

(51) Int. Cl. C23C 14/06; C23C 14/34; C23C 14/35

(52) U.S. Cl. 204/192.15; 204/298.13; 204/298.07; 204/298.12

(57) ABSTRACT

A sputtering target for a sputtering chamber comprises a sputtering plate composed of a chalcogenide material comprising an average yield strength of from about 40 MPa to about 120 MPa and a thermal conductivity of at least about 2.8 W/(m·K). In one version the sputtering plate is composed of a chalcogenide material with a stoichiometric ratio that varies by less than about 5% throughout the body of the sputtering plate. In another version, the sputtering plate is composed of a chalcogenide material having an average grain size of at least 20 microns, and an oxygen content of less than 600 weight ppm. The sputtering target is sputtered by applying a pulsed DC voltage to the sputtering target.

### BACKGROUND

Embodiments of the present invention relate to a sputtering target for a sputtering chamber used to process a substrate.

In the fabrication of circuits and displays, new materials and processes are constantly being developed to fabricate ever smaller active and passive features. For example, phase change memory materials can be used to form features having sizes of 45 nanometers or smaller for dynamic random access memory (DRAM) applications. Chalcogenides are a type of phase-changeable materials which undergo a phase transformation from a polycrystalline to an amorphous phase when activated by energy in the form of heat, electrons or photons, which allows fabrication of features sized 65 to 45 nanometers or smaller. Chalcogenides that exhibit phase transition include combinations of elements from Groups 11-16 of the IUPAC Periodic Table (also known respectively as Groups IB, IIB, IIIA, IVA, VA, and VIA). Suitable examples include AgSe, GeSb, GeSe, GeTe, SbTe, GeSbTe, GeSeTe, AgInSbTe, GeSbSeTe, TeGeSbS, and as well as other combinations, where these formulas are not being used to indicate empirical or stoichiometric ratios of the recited elements, but possible combinations of the elements, and these combinations can also be doped with additional elements.

Chalcogenide materials are often deposited by sputtering processes in which a sputtering target in a sputtering chamber is energetically bombarded by plasma species causing material to be knocked off the target and deposited onto a substrate. Typically, the sputtering chamber comprises an enclosure around a sputtering target facing a substrate support, a process zone into which a process gas is introduced, a gas energizer to energize the process gas to form the plasma, and an exhaust port to exhaust and control the pressure of the process gas in the chamber. The sputtering target includes a chalcogenide material to deposit chalcogenide on the substrate.

However, the sputtered material deposited on the substrate using conventional sputtering targets of chalcogenide often result in a high defect count in the deposited film. Process adders are particles sized greater than about 0.2 microns, which deposit on the sputtered film to form defects in the film. Most process adders are particulate contaminates which are formed during the sputtering process, and include grains from the sputtering target or process deposits which flake off from chamber surfaces or are knocked loose by the plasma species, and fall onto the substrate surface during processing. Particulate defect counts, as adder counts from conventional chalcogenide containing targets can be as high as 7,000 or even 12,000 defects per wafer for a 300 mm wafer. These high defect counts reduce device yields and increase manufacturing costs.

Thus it is desirable to have a sputtering target and process for depositing chalcogenide material on a substrate with low defect counts. It is further desirable to be able to deposit the sputtered film with reproducible and consistent results.

### DRAWINGS

The following description, claims, and accompanying drawings, illustrate exemplary embodiments of different features which can be used by themselves, or in combination with other features, and should not be limited to the exemplary versions shown in the drawings:

FIG. 1 is a sectional side view of an embodiment of a sputtering target comprising a sputtering plate mounted on a backing plate;

FIG. 1A is a top view of a sputtering target showing erosion grooves containing discrete pitted features;

FIG. 1B is a scanning electron micrograph showing the amorphous structure of the edges of the pitted features of FIG. 1A;

FIG. 1C is a scanning electron micrograph showing the chipped crystalline structure at the craters of the pitted features of FIG. 1A;

FIG. 2 is a sectional schematic view of a portion of the chalcogenide material of the sputtering plate showing grains and grain boundary regions;

FIG. 3 is a bar chart showing the number of defect particles, as represented by particle adders, measured in a sputter deposited chalcogenide layer versus the grain size of the chalcogenide material forming the sputtering target, which in turn is related to the yield strength of the chalcogenide material;

FIG. 4 is a plot showing the number of defect particles obtained for increasing target plasma hours comparing a conventional target with a target having a controlled grain size in cold and hot plasma configurations;

FIG. 5 is a plot showing the number of particle adders obtained in the sputtered chalcogenide layer for increasing pulsed DC frequency applied to the target.

FIG. 6 is a plot showing the particle adder count for increasing wafer number in a batch of wafers processed in a single process cycle, in which the pressure and plasma power level was varied over the process cycle;

FIG. 7 is an x-ray diffraction plot of the composition of the grains of a chalcogenide sputtering target;

FIG. 8 is a magnified view of a defect in the sputtering target, the defect comprising a nodule surrounded by a crater, which leads to particulate matter being formed in the sputtered film;

FIG. 8A is an x-ray diffraction pattern of the composition of the target material inside the crater, identified as area 8A in FIG. 8;

FIG. 8B is an x-ray diffraction pattern of the composition of the target material at the top of the nodule, identified as area 8B in FIG. 8;

FIG. 9 is a schematic sectional side view of a sputtering chamber showing a heat exchanger enclosing a rotating magnetic assembly and the backside surface of a sputtering target.

### SUMMARY

A sputtering target comprises a sputtering plate comprising a chalcogenide material having a yield strength of greater than about 40 MPa and a thermal conductivity of at least about 2.8 W/(m·K). A backing plate is provided for supporting the sputtering plate.

A sputtering chamber comprising the sputtering target also includes a magnetron comprising heat exchanger housing to provide heat transfer fluid about the backside surface of the backing plate and a plurality of rotatable magnets within the housing. A substrate support faces the sputtering target. A gas distributor introduces a gas into the sputtering chamber and a gas energizer energizes the gas to form a plasma to sputter the sputtering target. A gas exhaust port is provided to exhaust gas from the sputtering chamber.

A sputtering method for depositing a chalcogenide material on a substrate, comprises placing a substrate in a process zone to face a sputtering target comprising a chalcogenide material and having a yield strength of greater than about 40 MPa and a thermal conductivity of at least about 2.8 W/(m·K). A sputtered film comprising chalcogenide material is deposited on the substrate by introducing a sputtering gas to the process zone, applying a pulsed DC or RF voltage to the sputtering target, and removing the sputtering gas from the process zone.

Another version of a sputtering target comprises a sputtering plate comprising an average grain size of from about 18 to about 30 microns and a backing plate for supporting the sputtering plate.

### DESCRIPTION

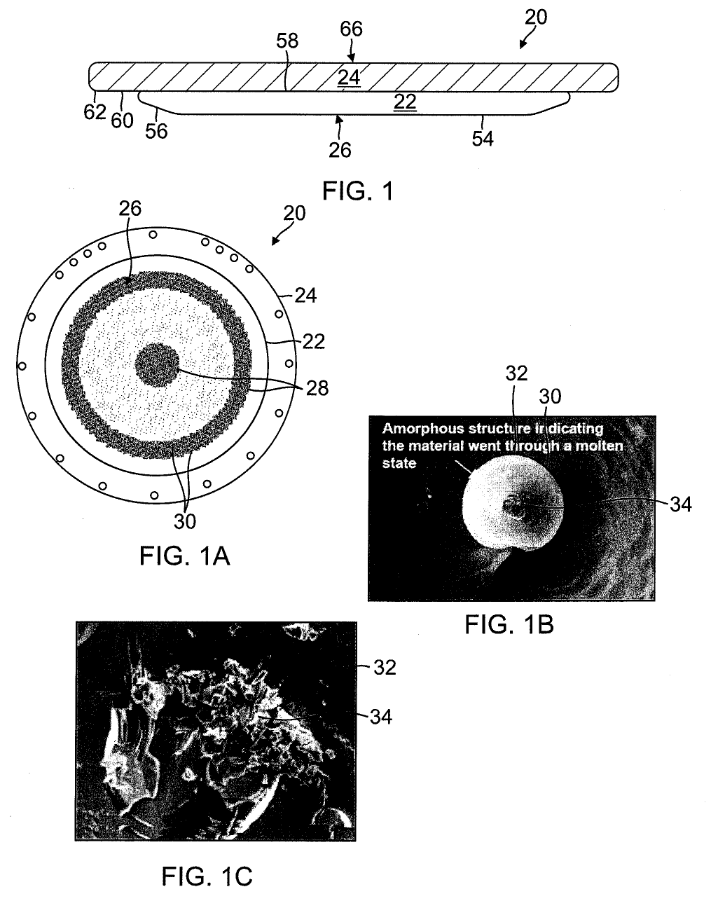

An embodiment of a sputtering target 20 comprising a sputtering plate 22 composed of a chalcogenide material, and mounted on a backing plate 24, is shown in FIG. 1. The sputtering plate 22 comprises sputtering material that includes chalcogenide material. The sputtering plate 22 can include other materials besides the chalcogenide material, or the sputtering plate can consist essentially of a chalcogenide material. The chalcogenide material can include a combination of elements from Groups 11-16 of the IUPAC Periodic Table (also known respectively as Groups IB, IIB, IIIA, IVA, VA, and VIA). Suitable examples include AgSe, GeSb, GeSe, GeTe, SbTe, GeSbTe, GeSeTe, AgInSbTe, GeSbSeTe, TeGeSbS, and other such combinations. The chalcogenide material can be a solid solution without a fixed stoichiometric ratio, or can have a definite stoichiometric ratio. In one version, the chalcogenide material comprises GeSbTe in a ratio of 2:2:5. Other materials which can be added to the GeSbTe chalcogenide include Bi, Sn, In or Si.

In the sputtering process, it was determined that uneven target sputtering caused erosion grooves 28 to form on the sputtering surface 26 of the target 20, as shown in FIG. 1A. In sputtering targets that produced higher levels of particulate contamination in the deposited films, as measured by the number of particle adders on the deposited film, the erosion grooves 28 were found to contain discrete pitted features 30. The electron micrograph images of FIGS. 1B and 1C, showed that these pitted features 30 have an amorphous structure 32 about their edges (FIG. 1B) and a chipped crystalline structure 34 at their craters (FIG. 1C). It is believed that such structures indicate that the target material passes through a molten state before a portion breaks off the target surface. The localized melting and breaking off of particles from the target surface is believed to cause the majority of particle adders or defect formation in the resultant sputtered film.

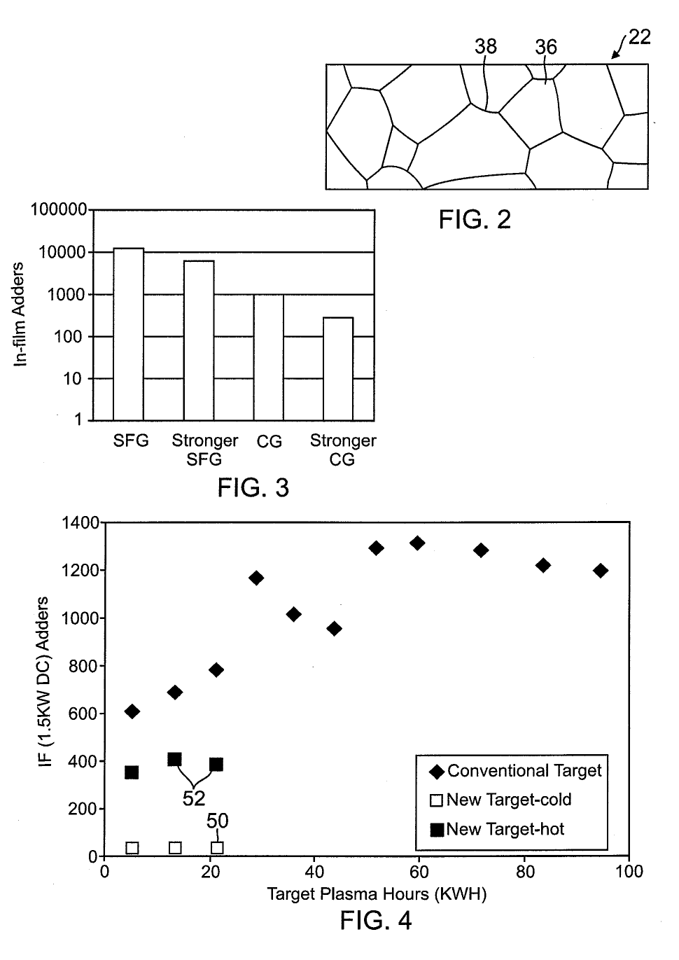

It was further discovered from experimentation, that a sputtering plate 22 comprising a chalcogenide material having a controlled yield strength and thermal conductivity provided lower defect counts, such as particle adders, in the resultant sputtered chalcogenide layer. The yield strength of the chalcogenide material is the stress at which the material starts to plastically deform. Prior to the yield point, the chalcogenide material deforms elastically and returns to its original shape when the applied stress is removed. However, once the yield point is passed, at least a fraction of the deformation is permanent and non-reversible. It is believed that the yield strength of the chalcogenide material is related to the bonding strength between individual grains, the uniformity of the grain structure, and the grain boundary regions, as schematically illustrated in FIG. 2. The bond strength of the chalcogenide material varies with its structure, for example, chalcogenide materials having different bond strengths have different grain sizes, average pore sizes and pore density. Chalcogenide material having a high bond strength, and consequently a high yield strength, typically have a controlled grain size, smaller average pore size and pore density as compared to a chalcogenide material having a low yield strength. In one version, the chalcogenide material has a yield strength of at least 40 MPa. In a further version, the chalcogenide material has a yield strength of from about 40 MPa to about 120 MPa.

The yield strength of chalcogenide material of the sputtering plate 22 can be measured using a three-point transverse stress test. In this test, two underlying points are used to support a test bar of the chalcogenide material, and a load is applied to the top of the test bar at a single overlying point which is located at a midpoint between the two underlying points. A controlled load is applied to the overlying point with increasing pressure until the chalcogenide test bar deforms and does not return to its original shape.

It is also desirable to control the thermal conductivity of the chalcogenide material used to form the sputtering plate 22. The chalcogenide material should have a relatively high thermal conductivity of at least about 2.8 W/(m·K) in order to provide sufficient heat dissipation through the bulk target material and backing plate to the cooling liquid. In contrast, traditional or conventional targets have a thermal conductivity which is typically less than 2.8. It is believed that larger numbers of particles result from conventional targets because the low conductivity causes high target surface temperature. In contrast, the present sputtering material comprises chalcogenide material which has a thermal conductivity of at least about 2.8 W/(m·K). In an additional version, the sputtering plate 22 can have a thermal conductivity of from about 3.0 to about 4.5 W/(m·K).

In still another version, the sputtering plate 22 comprises a chalcogenide material having an impurity level of less than 0.01%. In this version, the lower impurity level is desirable because it provides stronger bonding between the Be/Sb/Te material and reduce particle adder formation.

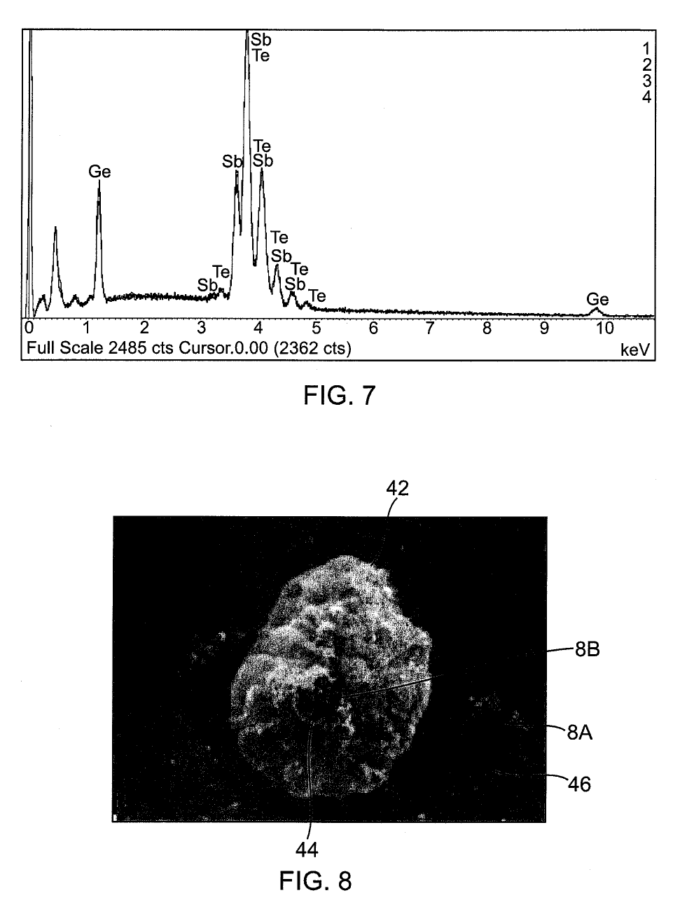

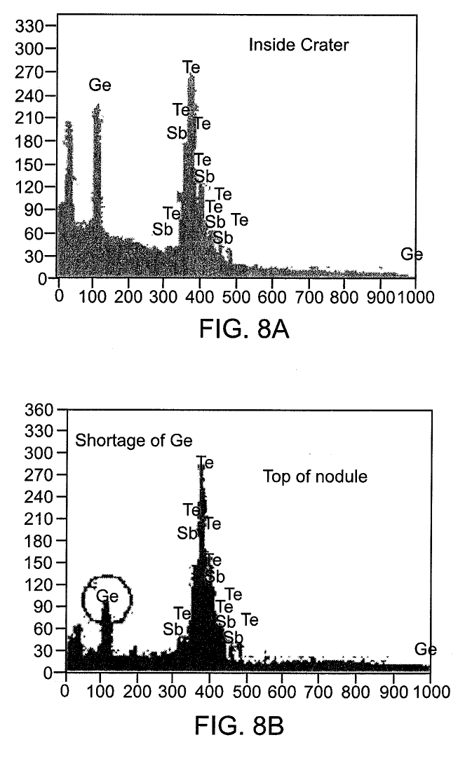

The chalcogenide material also desirably comprises a stoichiometric ratio that is uniform throughout the sputtering plate 22. In one version, the stoichiometric ratio of the chalcogenide material varies by less than 5% through the sputtering plate. For example, FIG. 7 shows an x-ray diffraction plot of the composition of the grains 36 of a chalcogenide sputtering target 20. It is desirable to have Ge:Sb:Te ratios. FIG. 8 shows an SEM magnified view of a defect 42 in the sputtering target 20, the defect 42 comprising a nodule 44 surrounded by a crater 46, which leads to a particle adder being formed in the sputtered film. Two X-ray diffraction plots were obtained to measure the composition of the crater material and the composition the nodule material, and these plots were then compared with the X-ray plot of the general composition of the chalcogenide material in FIG. 8, to identify compositional differences. FIG. 8A is an x-ray diffraction pattern of the composition of the target material inside the crater 46, identified as area 8A in FIG. 8. FIG. 8B is an x-ray diffraction pattern of the composition of the target material at the top of the nodule 44, identified as area 8B in FIG. 8. It is seen that the composition of the material at the top of the nodule 44 varies from the general composition of the target material by having a reduced amount of germanium. Thus, a target 20 having a reduced amount of such compositional variances would have fewer particle defect forming sites, such as the nodule/crater site. Accordingly, it is desirable to have a compositional variance across the sputtering target 20 which is less than 5%. It is believed that this ratio provides reduced particle adders on the sputtered film because uniform erosion of the target surface can be achieved. A desirable stoichiometric ratio for the elements Ge:Sb:Te is the ratio 2:2:5. However, other targets having other composition and stoichiometric ratio of elements can be selected based on the application.

It has also been discovered that when the surface of the chalcogenide material has a controlled pore distribution, reduced particle adders occur in the sputtered film. It is believed that the average pore size is important because pores that are too large expose the recessed regions of the sputtering plate 22 to bombardment and selective erosion by energized plasma species. Further, low pore density is important because excessively high concentration of pores allows sub-surface plasma bombardment over a larger surface. The average pore size and pore density can be measured by optically scanning one or more coupons of the sputtering target under a microscope. The bright and dark regions of the target surface can be analyzed to obtain an average diameter of the dark regions and an average number of dark regions per unit area of the target surface. For example, it is desirable to manufacture targets with a minimum number of pores. In one version the sputtering plate material is selected to have an average pore size of from about 0.2 to about 1.0 microns.

In still another version, the chalcogenide material of the sputtering plate 22 has a controlled grain size distribution to provide lower defect formation in a sputtered chalcogenide layer. In one embodiment, the chalcogenide material has an average grain size that is controlled to be within a selected range that provides lower defect concentration in a resultant sputtered material. For example, the chalcogenide material can have an average grain size of from about 18 to about 30 microns. FIG. 4 shows the number of defect particles obtained for increasing target plasma hours comparing a conventional target with a target having a controlled grain size in cold and hot plasma configurations. It is seen that the conventional target provides initial particle counts of 600 to 800, and after 50 kW·hr of plasma usage provides particle adder counts higher than 1200. In contrast, sputtering targets having an average grain size within the selected range of 18 to 30 microns, produce particle adder counts of about 400 in a hot plasma, and particle adder counts of less than 50 in a cold plasma configuration. The data was measured for the first 20 kW·hr of use for a target 20 operated while hot and a target operated while cold. The cold target data 50 is obtained from a chamber system that has been left sitting overnight. The chamber walls, target and target surface were at room temperature, about 70° C., when the cold target data 50 was taken. The hot target data 52 was obtained from a chamber system that had already had a pre-burn. After several wafers the chamber surfaces, including the walls and surface of the sputtering target 20 have a temperature of between about 300 and about 360° C. Both the hot target and the cold target were shown to produce dramatically fewer in-film adders as compared to the conventional target. The newer targets 20 also show a more steady particle count over the first 20 kW·hr of use, with hot target in-film particle counts between about 360 and about 400 and cold target in-film particle counts of between about 40 and about 60 for films obtained during the first 20 kW·hr of the target lifetime. The target 20, when operated at cold surface temperatures, provides the dramatic result of a 100-fold reduction of in-film particle counts as compared to the conventional chalcogenide target.

In one version, the chalcogenide material comprises grains 36 having a grain size that is maintained within a predetermined range. It is believed that the larger sized grains 36 provide better sputtering properties because they have a corresponding lesser surface area and grain boundary region, resulting in lower amounts of surface-residue contaminants. However, grains 36 that are too large can also be problematic because the bonding surface between the grains 36 is subject to greater sheer and strain forces per unit area. Thus, in one version, the chalcogenide material is selected such that at least about 80% of the grains 36 have a grain size in the range of from about 16 to about 25 microns. A cross-sectional view of chalcogenide material having grains 36 and grain boundary regions 38 is shown for example in FIG. 2. The cross-sectional photo can be obtained, for example, using scanning electron microscopy (SEM), optical microscopy with polished specimens, or other techniques that can provide a cross-sectional image of the grains 36 and grain boundary regions 38.

Yet another property of the sputtering plate 22 that is controlled to provide improved sputtering properties is the oxygen content of the chalcogenide material. It has been found that decreasing the oxygen content in the chalcogenide material improves the sputtering performance by reducing the number of defects formed in the sputtered film. This occurs because oxidation may weaken the Ge—Sb—Te bonding. Higher oxygen levels can increase defects because these materials occur in the interstitial spaces of the chalcogenide material causing lattice defects in the grains 36. Alternatively, the oxygen element can be formed as compounds in the grain boundary regions 38, and these result in increased erosion of the grain boundary regions 38 within the sputtering plasma, causing adjacent grains 36 of the chalcogenide at the sputtering surface 26 of the sputtering plate 22 to become loose, flake off, and fall to contaminate the substrate 40 being processed. Accordingly, the chalcogenide or other sputtering plate 22 is desirably composed of a chalcogenide material having an oxygen content of less than about than about 3000 wt. ppm (parts per million by weight), or even less than about 600 wt. ppm.

The sputtering plate 22 composed of the chalcogenide material is formed by a method which provides the desired yield strength and erosion resistant properties of the chalcogenide material. The resultant sputtering target can provide a sputtered film having a defect count of less than 100 when the sputtering target is sputtered with a plasma having a power density of less than about 4 W/cm².

In one suitable method for forming the chalcogenide material, a powder comprising chalcogenide is formed into a perform having a predetermined shape. The perform is pressed or sintered to form a sputtering plate 22 composed of sintered chalcogenide material having the desired grain sizes, grain boundary regions 38, and oxygen content. The rough shape of the perform can be set by placing the powder in a mold having the desired shape, and pressing the powder in the mold by isostatic or hot pressing methods. The grain sizes and pore size distribution can be controlled by controlling the temperature and pressure over the duration of the sintering process. To obtain larger grains it is desirable to increase crystal growth rates while reducing crystal nucleation rates. The oxygen content within the chalcogenide material can also be controlled by controlling the sintering atmosphere, for example, by sintering the ceramic perform in an inert or reducing gas. The sintered ceramic material can be further shaped, for example by at least one of machining, polishing, laser drilling, and other methods, to provide the desired sputtering plate 22.

Table 1 shows particle adder data for seven different chalcogenide sputtering targets 20 that were sputtered at a power density of about 1.5 W/cm² and at a pressure of about 1 mT. The Table columns include the average grain size grade, which included categories such as SFG—super fine grains (representing an average grain size of about 6 microns), stronger SFG (representing an average grain size of about 8 microns); stronger CG—coarse grains (representing an average grain size of about 20 microns); and stronger CG (representing an average grain size of 45 microns). The properties of each of these targets were measured and are shown in the following columns for target thermal conductivity, yield strength, grain size, average pore size, pore density, oxygen content (w. ppm) and thickness. Targets 2 and 5 had the highest yield strengths of the test series, 73.4 to 85.2 MPa and 71.6 to 82.9 MPa, respectively, and were found to generate the fewest in-film particle adders.

TABLE 1

| | κ | σ_{y} | Approx. Pore | Pore | | | | Grain size |
|---|---|---|---|---|---|---|---|---|
| Grade | [W/m · K] | [MPa] | size [μm] | density | Adders | O2 | Thickness | [μm] |
| SFG | 3.0 | 55.2-65.1 | 0.2-0.7 um | high | 12000 | 600 | 6.35 | 6 |
| Stronger-CG | 2.9 | 73.4-85.2 | 0.2-1.0 um | low | 274 | 2240 | 6.35 | 20 |
| Stronger-SFG | 3.0 | 63.3-68.9 | 0.2-0.7 um | high | 6211 | 450 | 8.00 | 8 |
| Stronger-CG | 2.8 | 69.8-80.7 | 0.4-1.0 um | low | 1350 | 2480 | 3.00 | 17 |
| Stronger-CG | 3.0 | 71.6-82.9 | 0.2-1.0 um | low | 463 | 2080 | 3.00 | 19 |
| Stronger-LG | 3.6 | 31.0-47.1 | 0.5-5.0 um | high | 2500 | 1620 | 6.35 | 45 |
| Stronger-CG | 2.9 | 47.8-62.7 | 0.2-1.5 um | high | 10000 | 830 | 6.00 | 12 |
| LowO2 | | | | | | | | |

The number of defect particles, or particle adders, measured in a sputter deposited chalcogenide layer versus the grain size of the chalcogenide material forming the sputtering target 20, is shown in the bar graph of FIG. 3. The grain size and bond strength are in turn related to the yield strength of the chalcogenide material. Four targets were tested under substantially the same process conditions. The super-fine-grain target was found to generate more than ten thousand particle adders in the deposited film. By comparison, the stronger bonded coarse grain target was found to generate only about 300 adders. The number of defect particles on a sputter deposited chalcogenide layer can be measured using a particle counter. In one version, the particle counter scans the deposited film and registers intensity of scattered light over a region of the sputtered film. The amount of light scattered from a piece of particulate matter is related to the particle's size and the counter can be set to count particles having a diameter greater than a predetermined diameter. The in-film particle count data presented herein was obtained with a particle counter that was set to count particles having a diameter of greater than about 0.2 microns. An appropriate particle counter can be, for example, a spherical optical counter such as SP1 available from KLA-Tencor, San Jose, Calif.

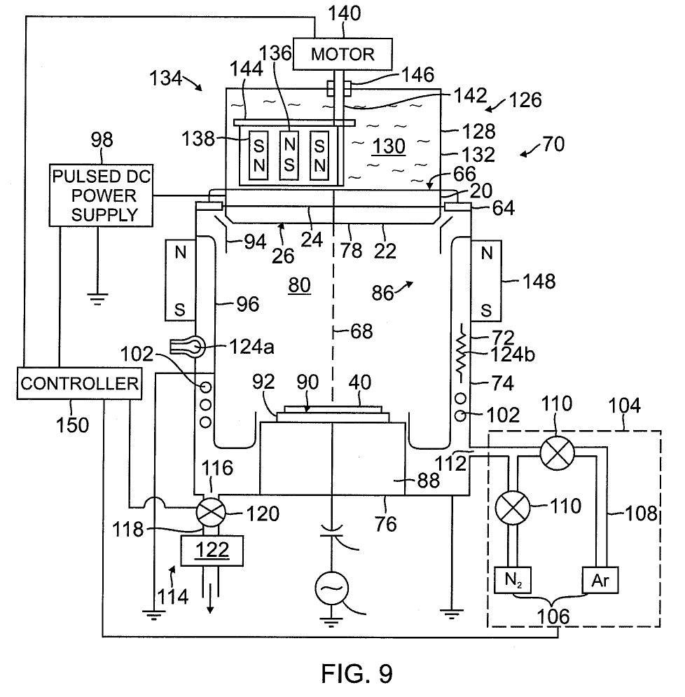

The configuration of the sputtering target 20 depends upon the type of chamber 70 and sputtering process in which the sputtering target 20 is used. Referring to FIG. 1, in one embodiment, the sputtering target 20 comprises a sputtering plate 22 having a central cylindrical mesa 54 that serves as a sputtering surface 26 and which has a top plane that is maintained parallel to the plane of a substrate 40 when the target 20 is mounted in a sputtering chamber 70, as shown in FIG. 9. In the exemplary embodiment shown, the top plane of the cylindrical mesa 54 is surrounded by a peripheral inclined rim 56. The inclined rim 56 can be inclined relative to the plane of the cylindrical mesa 54 by an angle α of at least about 8°, for example, from about 10° to about 20° or even about 15°.

The sputtering plate 22 is mounted on a backing plate 24 which has a front surface 58 to support the sputtering plate 22 and an annular flange 60 that extends beyond the radius of the sputtering plate 22. The annular flange 60 comprises a peripheral circular surface and has outer footing 62 that rests on an isolator 64 in the chamber 70, as shown in FIG. 9. The isolator 64 electrically isolates and separates the backing plate 24 from the chamber 70, and is typically a ring made from a ceramic material. The backing plate 24 is made from a material selected to have a high thermal conductivity, for example, at least about 220 W/(m·K), to reduce the operating temperature of the sputtering plate 22 mounted on the backing plate 24. A backing plate 24 having a high thermal conductivity allows the target 20 to be operated for longer process time periods by efficiently dissipating the heat generated in the target 20. In one version, the backing plate 24 is made from a metal, such as copper, stainless steel or aluminum. In another version, the backing plate 24 comprises a metal alloy, such as for example, a chromium-copper alloy.

An exemplary version of a sputtering process chamber 70 capable of processing a substrate 40 using the sputtering target 20 is shown in FIG. 9. The chamber 70 comprises enclosure walls 72 that enclose a plasma zone 80 and include sidewalls 74, a bottom wall 76, and a ceiling 78. The chamber 70 can be a part of a multi-chamber platform (not shown) having a cluster of interconnected chambers connected by a robot arm mechanism that transfers substrates 40 between the chambers. In the version shown, the process chamber 70 comprises a sputtering chamber, also called a physical vapor deposition or PVD chamber, which is capable of sputter depositing chalcogenide on a substrate 40. However, the chamber 70 can also be used for other purposes, such as for example, to deposit aluminum, copper, tantalum, titanium, tantalum nitride, titanium nitride, tungsten or tungsten nitride; thus, the present claims should not be limited to the exemplary embodiments described herein to illustrate the invention.

In one version the chamber 70 is equipped with a process kit to adapt the chamber 70 for different processes. The process kit comprises various components that can be removed from the chamber 70, for example, to clean sputtering deposits off the component surfaces, replace or repair eroded components. In one version, the process kit comprises a ring assembly (not shown) for placement about a peripheral wall of the substrate support 82 that terminates before an overhanging edge of the substrate 40. In one embodiment, the ring assembly comprises a deposition ring and a cover ring that cooperate with one another to reduce formation of sputter deposits on the peripheral walls of the support 82 or the overhanging edge of the substrate 40.

The process kit can also includes a shield assembly 86 that encircles the sputtering surface 26 of a sputtering target 20 and the peripheral edge of the substrate support 82, to reduce deposition of sputtering deposits on the sidewalls 74 of the chamber 70 and the lower portions of the support 82. The shield assembly 86 reduces deposition of sputtering material on the surfaces of support 82, and sidewalls 74 and bottom wall 76 of the chamber 70, by shadowing these surfaces. The shield assembly can comprise, for example, an upper shield 94 and a lower shield 96.

The chamber walls 72 can be equipped with temperature control components such as a radiative heater 124a or resistance heater or 124b components. The temperature control components serve to adjust the temperature of the chamber walls 72 and in one version can be used to set the temperature of the chamber walls to be within an optimal operating range for the desired process. For example, the radiative heater 124a and resistance heater 124b can be used to maintain the chamber walls at a temperature of from about 110° C. to about 200° C. in a sputter deposition process.

The process chamber 70 comprises a substrate support 82 to support the substrate 40 which comprises a pedestal 88. The pedestal 88 has a substrate receiving surface 90 that receives and supports the substrate 40 during processing, the surface 90 having a plane substantially parallel to a sputtering surface 26 of an overhead sputtering target 20. The support 82 can also include an electrostatic chuck 92 to electrostatically hold the substrate 40 and/or a heater (not shown), such as an electrical resistance heater or heat exchanger. In operation, a substrate 40 is introduced into the chamber 70 through a substrate loading inlet (not shown) in the sidewall 74 of the chamber 70 and placed on the substrate support 82. The support 82 can be lifted or lowered to lift and lower the substrate onto the support 82 during placement of a substrate 40 on the support. The pedestal 88 can be maintained at an electrically floating potential or grounded during plasma operation.

During a sputtering process, the target 20, support 82, and upper shield 94 are electrically biased relative to one another by a power supply 98. The target 20, upper shield 94, support 82, and other chamber components connected to the target power supply 98 operate as a gas energizer 100 to form or sustain a plasma of the sputtering gas. The gas energizer 100 can also include a source coil 102 that is powered by the application of a current through the coil 102. The plasma formed in the plasma zone 80 energetically impinges upon and bombards the sputtering surface 26 of the target 20 to sputter material off the surface 26 onto the substrate 40.

The sputtering gas is introduced into the chamber 70 through a gas delivery system 104 that provides gas from a gas supply 106 via conduits 108 having gas flow control valves 110, such as a mass flow controllers, to pass a set flow rate of the gas therethrough. The gases are fed to a mixing manifold (not shown) in which the gases are mixed to form a desired process gas composition and fed to a gas distributor having gas outlets 112 in the chamber 70. The process gas supply 106 may comprise a non-reactive gas, such as argon or xenon, which is capable of energetically impinging upon and sputtering material from a target. The process gas supply 106 may also include a non-reactive gas such as argon, or a reactive gas such as an oxygen-containing gas or a nitrogen-containing gas, that are capable of reacting with the sputtered material to form a layer on the substrate 40.

Spent process gas and byproducts are exhausted from the chamber 70 through an exhaust 114 which includes exhaust ports 116 that receive spent process gas and pass the spent gas to an exhaust conduit 118 having a throttle valve 120 to control the pressure of the gas in the chamber 70. The exhaust conduit 118 is connected to one or more exhaust pumps 122. Typically, the pressure of the sputtering gas in the chamber 70 is set to sub-atmospheric levels, such as a vacuum environment, for example, gas pressures of 1 mTorr to 400 mTorr.

In one version, the voltage bias applied to the target 20 can be a continuous DC (direct current) voltage or a pulsed DC voltage. The pulsed DC voltage can be oscillated between negative and positive states, which represent “on” and “off” states. In one version of the sputtering process, the electrical power applied to the target 20 is pulsed between a negative voltage and a positive voltage, relative to ground. The pulsed voltage bias is provided by the target power supply 98. Sputtering occurs when the target 20 is biased with a negative voltage relative to ground, and substantially no sputtering occurs when the target 20 is biased with a positive voltage relative to ground. Thus, each voltage pulse has a duty cycle, with a “on” cycle when the target 20 is negatively biased, and a “off” cycle when the target 20 is positively biased. During the negative voltage pulse, ionized sputtering gas species are accelerated to the target 20 to sputter material from the target. During the positive voltage pulse, the surface of the target 20 becomes positively charged to repel positive charge accumulated on the surface of the target 20. Thus, during the positive phase of the duty cycle, accumulation of positive charges on the target surface is prevented, thereby reducing arcing from the target surface which would otherwise occur if the pulsed duty cycle, were not used.

The magnitude of the positive or negative voltage bias applied to the target 20 depends on the electrical resistivity of the target and the current carried by the energized gas. In one embodiment, during the “on” cycle, the target 20 is biased with a negative voltage of from about −200 to about −600 volts relative to ground, however, other voltage ranges can also be used depending on the electrical resistivity of the target material. In the same embodiment, during the “off” cycle, the target 20 is positively biased relative to ground with a positive voltage of from about +20 about +60 volts. In one embodiment, the pulse frequency range is from about 5 to about 250 kHz, for example, in one version, the pulse frequency is set at about 25 kHz. The pulsed DC power is applied at a power level of at least about 3 kW, or even from about 0.5 to about 8 kW.

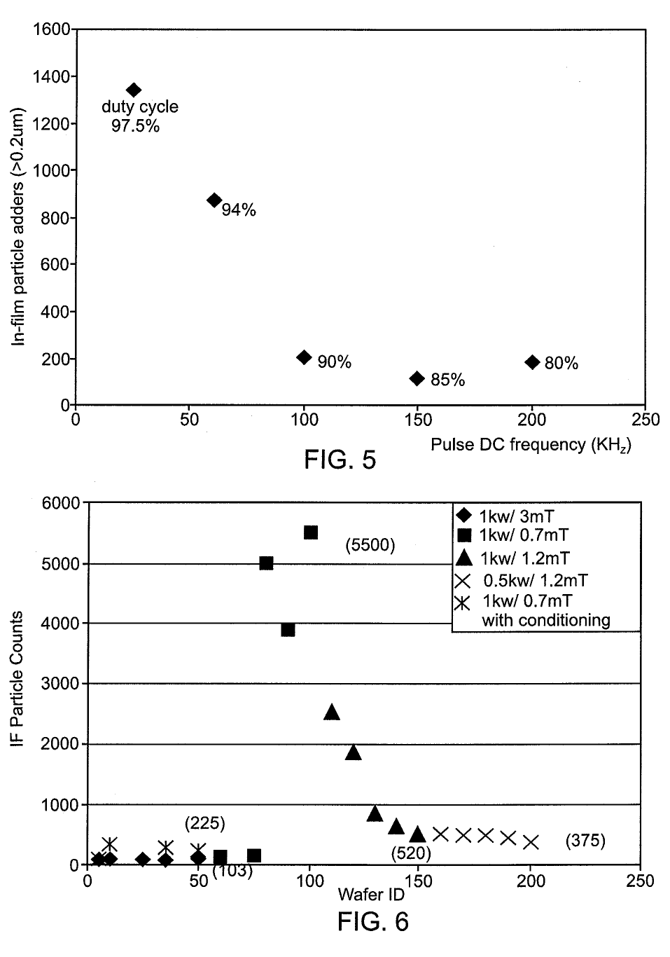

For example, FIG. 5 shows a plot of the number of particle adders obtained in the sputtered chalcogenide layer for increasing pulsed DC frequency applied to the target 20. It is seen that a duty cycle of 97.5%, which corresponds to a positive bias for about 1 microsecond, and a negative bias for about 39 microseconds per 40 microsecond period, provides a particle adder count of over 1200. In contrast, smaller duty cycles of under 90% provide much lower particle adder counts of 200 or less. Similarly, FIG. 6 shows particle adder counts updated for increasing wafer number in a batch of wafers processed in a single process cycle. In this cycle, the pressure and plasma power level was varied over the process cycle. It was determined that maintaining a pressure range of from about 1.2 to about 3 mTorr provided optimal particle adder counts of less than 2000. In contrast, operating the process at 0.7 mTorr provided at adder counts exceeding 4000.

Elemental material sputtered from the target 20 by itself, or combined with other gaseous species in the chamber 70 deposits to form a chalcogenide film on the substrate 40. It is believed that the pulsed DC voltage applied to the target 20 provides a better film as it results in charge dissipation of positive or negative charges from the surface of the target 20. The chalcogenide material does not always allow accumulated charge to dissipate over time when exposed to the plasma environment containing charged ions and other species. The pulsed DC voltage alleviates this problem by maintaining “on” and “off” states during each pulse cycle. During the off period, the charge accumulated on the target surface has enough time to be discharged. Hence, such charge accumulation is reduced and prevented from impeding the sputtering process. Absent the “off” portion of the pulse cycle, the charge accumulated on the target surface gradually reduces the deposition rate and may eventually even cause the plasma to be extinguished.

The chamber 70 can also include a heat exchanger 126 comprising a housing 128 capable of holding a heat transfer fluid 130 which is mounted abutting the backside surface 66 of the target 20. The housing 128 comprises walls 132 which are sealed about the backside surface 66 of the target 20. A heat transfer fluid 130, such as chilled deionized water, is introduced into the housing 128 though an inlet and is removed from the housing through an outlet (not shown). The heat exchanger 126 serves to maintain the target 20 at lower temperatures to reduce the possibility of forming erosion grooves 28 and microcracks in the target 20.

The chamber 70 can also include a magnetic field generator 134 comprising a plurality of rotatable magnets 136, 138 which are positioned about the backside surface 66 of the backing plate 24 of the target 20. The rotatable magnets 136, 138 can include a set of magnets which include a central magnet 136 having a first magnetic flux or magnetic field orientation, and a peripheral magnet 138 with a second magnetic flux or magnetic field orientation. In one version, the ratio of the first magnetic flux to the second magnetic flux is at least about 1:2, for example, from about 1:3 to about 1:8, or even about 1:5. This allows the magnetic field from the peripheral magnets 138 to extend deeper into the chamber 70 towards the substrate 40. The chamber can also include stationary magnets 148 to further shape and direct the flow of plasma within the chamber 70 and to extend the magnetic field region towards the substrate. In one example, the magnetic field generator 134 comprises a set of central magnets 136 having a first magnetic field orientation, surrounded by a set of peripheral magnets 138 having a second magnetic field orientation. For example, the second magnetic field orientation can be generated by positioning the peripheral magnets 138 so that their polarity direction is opposite to the polarity direction of the central magnets 136. To achieve uniform sputtering onto the substrate 40, in the version shown, the magnetic field generator 134 comprises a motor 140 and axle 140 to rotate a circular plate 144 on which the magnets 136,138 are mounted about a central axis 68 of the chamber 70. The rotation system rotates the rotatable magnets 136,138 at from about 60 to about 120 rpm, for example, about 80 to about 100 rpm. In one version, the magnets 136,138 comprise NdFeB. The rotating magnets 136, 138 provide a rotating and changing magnetic field about the sputtering surface 26 of the sputtering target 20 which affects sputtering rates from the target, while also circulating the heat transfer 130 fluid in the housing 128 of the heat exchanger 126.

The rotating magnets 136, 138 can be part of a magnetron or magnetron assembly that provides a time-varying magnetic field to the sputtering surface 26 of the sputtering target 20. In one embodiment, the magnetron further comprises a heat exchanger housing 128 to provide heat transfer fluid about the backside surface of the backing plate 24. The plurality of rotatable magnets can circulate the heat transfer 130 fluid in the housing 128 of the heat exchanger 126, aiding heat transfer between the backside surface 66 of the backing plate 24 and the heat transfer fluid 130.

It has been found that the choice of magnet assembly influences the level of particle adder defects in the sputtered film. Butterfly, DSTTN and C&F magnet assemblies and their respective defect rates are compared in Table 2. The Butterfly magnet assembly produced in-film defects at an average of greater than about 200 adders per wafer over a 50-waver run, whereas the DSTTN magnet produced in-film defects at an average of about 125 adders per wafer over a 50-wafer run, and the C&F magnet assembly produced a much higher number of defects, averaging about 7000 defects per wafer over a 25 wafer run. It is believed that the DSTTN magnet assembly produces fewer in-film particle adders because the erosion area of the DSTTN magnet assembly is significantly larger than the erosion area of the Butterfly and C&F Magnet assemblies. This larger erosion area means that the plasma power is incident on the sputtering surface 26 with a lower power density and hence the surface does not get as hot in the erosion area.

TABLE 2

| Magnet | Erosion area | Defect level |
|---|---|---|
| Butterfly | 31 | Bad |
| DSTTN | 79 | Better |
| C&F Magnet | 23 | Worse |

To counteract the large amount of power delivered to the target 20, the back of the target 20 may be sealed to a backside coolant chamber. Chilled deionized water or other cooling liquid is circulated through the interior of the coolant chamber to cool the target 20. Portions of the magnetic field generator 134 are typically immersed in the cooling water, and the axle 142 of the generator 134 passes through the backside coolant chamber through a rotary seal 146.

The chamber 70 is controlled by a controller 150 that comprises program code having instruction sets to operate components of the chamber 70 to process substrates 40 in the chamber 70. For example, the controller 150 can comprise program code that includes a substrate positioning instruction set to operate the substrate support 82 and substrate transport; a gas flow control instruction set to operate gas flow control valves 110 to set a flow of sputtering gas to the chamber 70; a gas pressure control instruction set to operate the throttle valve 120 to maintain a pressure in the chamber 70; a gas energizer control instruction set to operate the gas energizer 100 to set a gas energizing power level; a temperature control instruction set to control a temperature control system (not shown) in the support 82 or in the wall 72 (124a,b) to set temperatures of the substrate 40 or walls 72, respectively; and a process monitoring instruction set to monitor the process in the chamber 70.

The sputtering process can be used to deposit a layer comprising a chalcogenide compound on a substrate 40. The chalcogenide material can be in the form of a layer, or other shape, and can be used by itself, or in combination with other overlying or underlying layers. For example, a chalcogenide layer can be used as a phase-change layer between electrodes in a PCM or P-RAM structure. In another example, the chalcogenide layer can be deposited on a substrate 40 comprising a silicon wafer and subsequently etched or shaped to form regions of phase-change material. A chalcogenide layer deposited from the present sputtering target 20 can a particle adder count of less than 300, or even less than 100.

The present invention has been described with reference to certain preferred versions thereof; however, other versions are possible. For example, the sputtering plate 22 and backing plate 24 of the target 20 can be made from other materials than those described herein, and can also have other shapes and sizes. Therefore, the spirit and scope of the appended claims should not be limited to the description of the preferred versions contained herein.

What is claimed is:

1. A sputtering target comprising:
(a) a sputtering plate comprising a chalcogenide material having a yield strength of greater than about 40 MPa and a thermal conductivity of at least about 2.8 W/(m·K); and
(b) a backing plate for supporting the sputtering plate.

2. A target according to claim 1 wherein the chalcogenide material comprises an impurity level of less than 0.01%.

3. A target according to claim 1 wherein the chalcogenide material comprises a stoichiometric ratio that varies by less than 5% throughout the sputtering plate.

4. A target according to claim 1 wherein the chalcogenide material comprises:
(i) a yield strength of from about 40 MPa to about 120 MPa; and
(ii) a thermal conductivity of from about 2.8 to about 4.5 W/(m·K),
whereby a sputtered film from the sputtering target provides a defect count of less than 100 when the sputtering target is sputtered with a plasma having a power density of less than about 4 W/cm².

5. A target according to claim 1 wherein the chalcogenide material comprises an average grain size of from about 5 to about 50 microns.

6. A target according to claim 1 wherein the chalcogenide material further comprises an oxygen content of less than about 600 weight ppm.

7. A target according to claim 1 wherein the sputtering plate comprises a cylindrical mesa having a top plane and a peripheral inclined rim surrounding the top plane, and the backing plate comprises an annular flange that extends radially outward from the sputtering plate.

8. A sputtering chamber comprising:
(a) a sputtering target comprising:
(i) a sputtering plate comprising a chalcogenide material having a yield strength of greater than about 40 MPa and a thermal conductivity of at least about 2.8 W/(m·K); and
(ii) backing plate for supporting the sputtering plate, the backing plate having a backside surface;
(b) a magnetron comprising:
(i) heat exchanger housing to provide heat transfer fluid about the backside surface of the backing plate; and
(ii) a plurality of rotatable magnets within the housing;
(c) a substrate support facing the sputtering target;
(d) a gas distributor to introduce a gas into the sputtering chamber;
(e) a gas energizer to energize the gas to form a plasma to sputter the sputtering target; and
(f) a gas exhaust port to exhaust gas from the sputtering chamber.

9. A chamber according to claim 8 wherein the sputtering plate comprises a cylindrical mesa having a top plane and a peripheral inclined rim surrounding the top plane, and the backing plate comprises an annular flange that extends radially outward from the sputtering plate.

10. A chamber according to claim 8 wherein the target is biased by a pulsed DC power supply or an RF power supply.

11. A sputtering method for depositing a chalcogenide material on a substrate, the method comprising:
(a) placing a substrate in a process zone to face a sputtering target comprising a chalcogenide material and having a yield strength of greater than about 40 MPa and a thermal conductivity of at least about 2.8 W/(m·K); and
(b) depositing a sputtered film comprising chalcogenide material on the substrate by introducing a sputtering gas to the process zone, applying a pulsed DC or RF voltage to the sputtering target, and removing the sputtering gas from the process zone.

12. A method according to claim 11 comprising applying the pulsed DC voltage to the sputtering target with a frequency of from about 20 to about 260 kHz and a reverse bias time of less than 5 microseconds per pulsing period.

13. A method according to claim 11 comprising applying a pulsed DC voltage that is pulsed on and off, the on voltage comprising a value of from about −200 V to about −600 volts and the off voltage comprising a value of from about +20 to about +60 volts.

14. A sputtering target comprising:
(a) a sputtering plate comprising an average grain size of from about 18 to about 30 microns; and
(b) backing plate for supporting the sputtering plate.

15. A target according to claim 14 wherein at least about 40% of the grains have a grain size of from about 18 to about 30 microns.

16. A target according to claim 14 wherein at least about 40% of the grains have an average grain size of at least 20 microns.

17. A target according to claim 1 wherein the chalcogenide material further comprises an oxygen content of less than about 600 weight ppm.

18. A target according to claim 14 wherein the chalcogenide material having a yield strength of greater than about 40 MPa and a thermal conductivity of at least about 2.8 W/(m·K).

19. A target according to claim 14 wherein the chalcogenide material comprises an impurity level of less than 0.01%.

20. A target according to claim 14 wherein the chalcogenide material comprises a stoichiometric ratio that varies by less than 5% throughout the sputtering plate.

21. A target according to claim 14 wherein the chalcogenide material comprises:
(i) a yield strength of from about 40 MPa to about 120 MPa; and
(ii) a thermal conductivity of from about 2.8 to about 4.5 W/(m·K),
whereby a sputtered film from the sputtering target provides a defect count of less than 100 when the sputtering target is sputtered with a plasma having a power density of less than about 4 W/cm².

22. A target according to claim 14 wherein the sputtering plate comprises a cylindrical mesa having a top plane and a peripheral inclined rim surrounding the top plane, and the backing plate comprises an annular flange that extends radially outward from the sputtering plate.
